(19) United States
(12) Patent Application Publication
(10) Pub. No.: US 2026/0023289 A1
(43) Pub. Date: Jan. 22, 2026

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Fei AI, Wuhan, Hubei (CN); Zhilin WU, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/996,980

(22) PCT Filed: Mar. 31, 2023
(86) PCT No.: PCT/CN2023/085666

§ 371 Date: Jan. 18, 2025

(30) Foreign Application Priority Data
Nov. 1, 2022 (CN) 202211358193.9

(51) Int. Cl. G02F 1/1345; H05K 1/18

(52) U.S. Cl. CPC G02F 1/13452; G02F 1/13458; H05K 1/189; H05K 2201/10136

(57) ABSTRACT

The present disclosure provides a display panel and display device. The display panel includes a substrate, a first binding layer, and a first insulating layer. A first notch is formed in an area of the first insulating layer close to a side surface, a first protrusion portion is disposed on a binding terminal and formed in the first notch, and the first protrusion portion is in contact with a first surface, thereby improving an effective conductive area of the binding area, improving the conductivity of a line, increasing the number of conductive electrons, decreasing the contact impedance, reducing the risk of abnormal binding, and improving the product yield.

### TECHNICAL FIELD

The present disclosure relates to the field of display technologies, and more particularly, to a display panel and a display device.

### BACKGROUND

Liquid Crystal Displays (LCDs) have advantages such as high picture quality, power saving, and thin body, and are widely applied to various consumer electronic products. With increasing demand for the screen-to-body ratio of thin and light electronic products, display technology is developing towards extremely narrow frames. COF, as an abbreviation of “Chip On FPC”, is one of existing dominant technologies and means a chip 4 bound to a flexible circuit board 3. Specifically, FIGS. 1a to 1c are schematic diagrams of a binding structure of a display device according to the prior art, in which the display device includes a COF and a display panel formed by a pair of an array substrate 1 and a color film substrate 2. FIG. 1a shows that the COF is bound to the array substrate 1, so that the size of the frame can be reduced. However, this arrangement cannot meet the increasing requirements for the screen-to-body ratio of the full screen.

To reach an extremely narrow border, the COF may be bound to a side surface of the display panel, as shown in FIG. 1b. Specifically, a substrate 10, a buffer layer 11, a first binding layer 12, a first insulating layer 13, a second binding layer 14, a second insulating layer 15, and a third binding layer 16 are first formed, in which the first binding layer 12 includes a plurality of first wirings 121, the second binding layer 14 includes a plurality of second wirings 141, and the third binding layer 16 includes a plurality of third wirings 161, as shown in FIG. 1c. The side surface of the display panel is then sputter coated and patterned to form a binding terminal 17. Next, the flexible circuit board 3 is electrically connected to the binding terminal 17. In the conventional side binding structure, the contact conductive areas of the binding terminal 17 to the array substrate are the side surfaces of the first wirings 121, the second wirings 141, and the third wirings 161. Due to the limitation of a film thickness and area of the first wirings 121, the second wirings 141, and the third wirings 161, the effective conduction area between the binding terminal 17 and the wirings of the array substrate is limited, causing a poor conductivity of lines, a low number of electrically conductive electrons, a high contact impedance, and a decreased yield. Therefore, it is necessary to solve this defect.

### SUMMARY

### Technical Problems

Embodiments of the present disclosure provide a display panel, which can solve a problem of a poor conductivity of lines, a low number of electrically conductive electrons, a high contact impedance, and a decreased yield caused by the limited effective conduction area of the side binding structure of the display panel in the prior art.

### Technical Solutions

To solve the above problem, the present disclosure provides the following technical solutions.

Embodiments of the present disclosure provide a display panel including:

a substrate, in which a binding terminal is disposed on at least a side surface of the substrate;

a first binding layer on the substrate, the first binding layer including a plurality of first wirings, the first wirings including a first surface; and

a first insulating layer in contact with the first surface, in which a first notch is disposed in an area of the first insulating layer close to the side surface.

A first protrusion portion is disposed on the binding terminal and formed in the first notch to be in contact with the first surface.

Embodiments of the present disclosure further provide a display device including a flexible circuit board and a display panel, the flexible circuit board being electrically connected to a binding terminal of the display panel, the display panel including:

a substrate, in which a binding terminal is disposed on at least a side surface of the substrate;

a first binding layer on the substrate, the first binding layer including a plurality of first wirings, the plurality of first wirings including a first surface; and

a first insulating layer in contact with the first surface, in which a first notch is disposed in an area of the first insulating layer close to the side surface.

A first protrusion portion is disposed on the binding terminal and formed in the first notch to be in contact with the first surface.

### Beneficial Effect

Embodiments of the present disclosure provide a display panel including a substrate, a first binding layer, and a first insulating layer. At least a side surface of the substrate is provided with a binding terminal. The first binding layer is disposed on the substrate and includes a plurality of first wirings, and the first wirings include a first surface. A first insulating layer is in contact with the first surface. A first notch is formed in an area of the first insulating layer close to the side surface. A first protrusion portion is disposed on the binding terminal and formed in the first notch to be in contact with the first surface. According to the present disclosure, the first notch is formed in the area of the first insulating layer close to the side surface, the first protrusion portion is formed on the binding terminal and in the first notch, and the first protrusion portion is in contact with the first surface, so that the contact area between the binding terminal and the first binding layer is increased, the effective conduction area of the binding area is improved, the conductivity of the lines is improved, the number of conductive electrons is large, the contact impedance is low, the risk of abnormal binding is reduced, and the product yield is improved.

### BRIEF DESCRIPTION OF THE DRAWINGS

FIGS. 1a to 1c are schematic diagrams of a binding structure of a display device according to the prior art.

FIG. 2 is a top view of a display panel according to some embodiments of the present disclosure.

FIG. 3 is a cross-sectional view of a first structure of the display panel in FIG. 2 taken along a A-A′ direction.

FIGS. 4a to 4d are schematic diagrams of basic structures of components in a first manufacturing process of a display panel according to some embodiments of the present disclosure.

FIG. 5 is a cross-sectional view of a second structure of the display panel in FIG. 2 taken along the A-A′ direction.

FIG. 6 is a cross-sectional view of a third structure of the display panel in FIG. 2 taken along the A-A′ direction.

FIG. 7 is a cross-sectional view of a fourth structure of the display panel in FIG. 2 taken along the A-A′ direction.

FIGS. 8a to 8c are schematic diagrams of basic structures of components in a second manufacturing process of a display panel according to some embodiments of the present disclosure.

FIG. 9 is a cross-sectional view of a fifth structure of the display panel in FIG. 2 taken along the A-A′ direction.

FIG. 10 is a schematic diagram of basic structures of components of a display panel according to some embodiments of the present disclosure.

FIGS. 11a to 11c are schematic diagrams of basic structures of components in a manufacturing process of a display device according to some embodiments of the present disclosure.

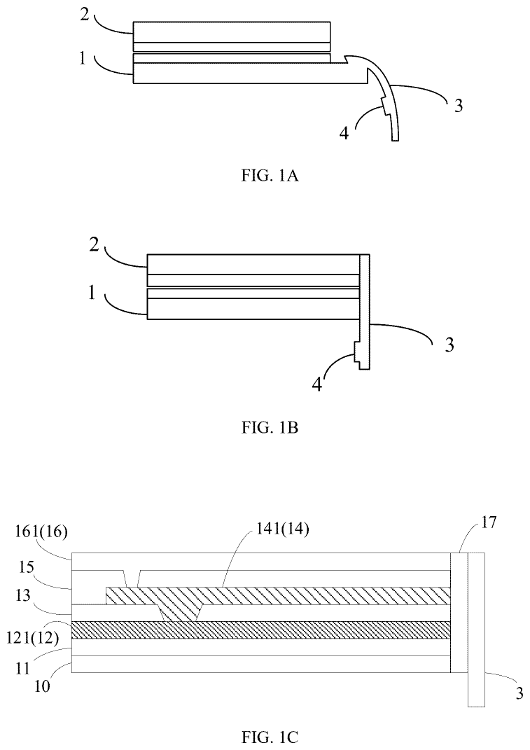

### DETAILED DESCRIPTION OF THE EMBODIMENTS

In order to make the objective, technical solutions and effect of the present disclosure clear and explicit, the present disclosure provides a display panel and a display device, which will be described in detail below with reference to the accompanying drawings and examples. In the drawings, for clarity and ease of understanding and description, the dimensions and thicknesses of the components depicted in the drawings are not to scale. It is to be understood that the specific embodiments described herein are merely illustrative of the present disclosure and are not intended to limit the present disclosure.

According to the prior art, the effective conduction area of the side binding structure of the display panel is limited, causing a poor conductivity of lines, a low number of conductive electrons, a high contact impedance, and a decreased yield, which can be solved by the embodiments of the present disclosure.

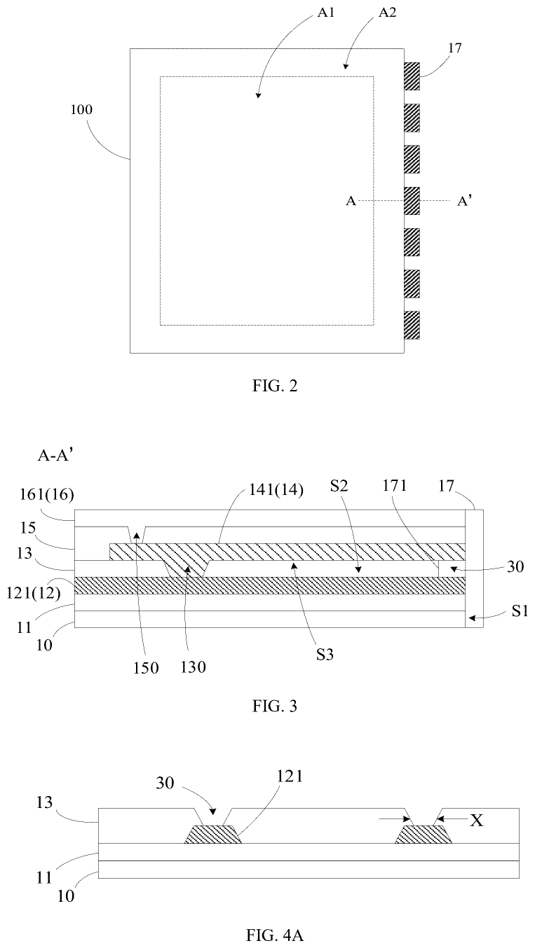

FIG. 2 is a top view of a display panel according to some embodiments of the present disclosure. The display panel 100 includes a display area A1 and a frame area A2 disposed around the display area A1. The display panel 100 includes binding terminals 17 disposed on a side surface of the display panel 100. The present disclosure achieves an extremely narrow frame by using a side binding process.

Specifically, referring to FIG. 3, it is a cross-sectional view of a first structure of the display panel in FIG. 2 taken along a A-A′ direction. The display panel 100 includes a substrate 10, a first binding layer 12, and a first insulating layer 13. The binding terminals 17 are disposed on at least a side surface S1 of the substrate 10. The first binding layer 12 is disposed on the substrate 10 and includes a plurality of first wirings 121. The first wirings 121 include a first surface S2. The first insulating layer 13 is in contact with the first surface S2. First notches 30 are formed in an area of the first insulating layer 13 close to the side surface S1. Each binding terminal 17 includes a first protrusion portion 171 that is formed in each corresponding first notch 30 and contacted with the first surface S2.

It is to be understood that according to the present disclosure, the first notch 30 is formed in the area of the first insulating layer 13 close to the side surface S1, and the binding terminal 17 includes the first protrusion portion 171 that is formed in the first notch 30 and contacted with the first surface S2. By adopting the technical solution of the present disclosure, while the binding terminal 17 contacts the side surface of the first wirings 121, the first protrusion portion 171 can further contact the first surface S2, so that the effective conduction area of the binding area is improved, the conductivity of the lines is improved, the number of conductive electrons is large, the contact impedance is low, the risk of abnormal binding is reduced, the product reliability is improved, and the product yield is increased.

It is to be noted that the first surface S2 of the first wirings 121 is shown in FIG. 3 as an upper surface, and in other embodiments, the first surface S2 may also be a lower surface.

It is to be understood that according to the present disclosure, when the first notch 30 is formed at the first insulating layer 13, and the binding terminal 17 is subsequently formed by sputter coating and patterning, a part of the sputtered material (that is, the first protrusion portion 171) is deposited in the first notch 30 and in contact with the first surface S2, thereby increasing the contact area between the binding terminal 17 and the first binding layer 12, and improving the binding effect.

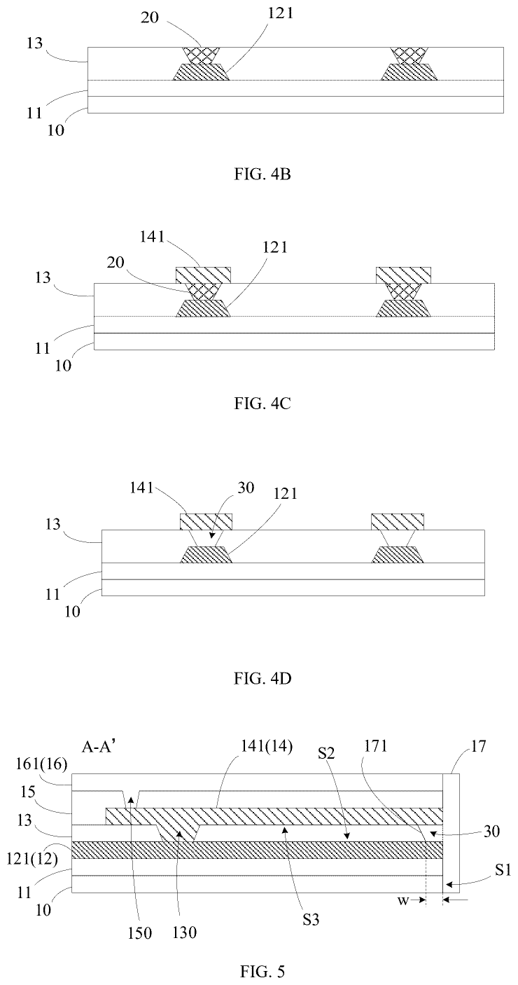

In one embodiment, the first surface S2 is disposed close to a light-emitting side of the display panel 100. That is, the first surface S2 is the upper surface. In a direction parallel to the first surface S2 and the side surface S1, that is, a direction of the intersection line between the first surface S2 and the side surface S1, a width X of the first notch 30 gradually increases along a light-emitting direction of the display panel 100 (for example, referring to FIG. 4a).

Specifically, FIGS. 4a to 4d illustrate a first formation process of the first notch 30 and are schematic diagrams of basic structures of components in a first manufacturing process of a display panel according to some embodiments of the present disclosure. It is to be noted that FIGS. 4a to 4d are side views of the display panel 100.

First, referring to FIG. 4a, a buffer layer 11 is formed on the substrate 10, and the first binding layer 12 is formed on the buffer layer 11. The first binding layer 12 is patterned to form the plurality of first wirings 121. The first insulating layer 13 is then formed on the plurality of first wirings 121. The first notches 30 are formed at the first insulating layer 13 to expose the first surface S2 of the first wirings 121.

Next, referring to FIG. 4b, an organic layer 20, such as a polymer layer, is formed in the first notches 30.

Next, referring to FIG. 4c, other film layers for constituting the display panel are formed on the first insulating layer 13 and the organic layer 20, wherein a plurality of second wirings 141 are only shown in FIG. 4c.

Next, referring to FIG. 4d, after the preparation of the film layers other than the binding terminals 17 is completed, the display panel is turned over 90 degrees, so that the side surface S1 of the substrate 10 faces upwards and the organic layer 20 on the side surface S1 is exposed. Then, the organic layer 20 is removed, and the first notches 30 are retained. When the binding terminals 17 are subsequently formed by sputter coating and patterning, a part of the sputtered material (that is, the first protrusion portions 171) are deposited in the first notches 30 and are in contact with the first surface S2 (for example, referring to FIG. 3).

It is to be noted that the organic layer 20 may be removed using an etching solution, a stripping solution, laser positioning, or the like. A depth of each first notch 30 is greater than 0 and less than or equal to 1 millimeter in a direction perpendicular to the side surface S1 of the substrate 10.

It is to be understood that by using the method illustrated in FIGS. 4a to 4d, the organic layer 20 is filled in the first notches 30, and then removed before the formation of the binding terminals 17 on the side surface S1 of the substrate 10 by sputter coating and pattering, so that the first notches 30 cannot be covered by other film layers on the first insulating layer 13, thereby increasing the contact area between the binding terminals 17 and the first binding layer 12.

It is to be noted that according to the method illustrated in FIGS. 4a to 4d, the first notches 30 are formed at the first insulating layer 13 to increase the contact area between the binding terminals 17 and the first binding layer 12. In other embodiments, the formation of a notch at the buffer layer 11 can also achieve the effect of increasing the contact area of the binding terminals 17 and the first binding layer 12. In summary, the technical solution of forming the notches at the insulating layer disposed on a side of the first binding layer 12 to increase the effective conductive area of the binding area is within the scope of the present disclosure.

In one embodiment, the display panel 100 includes a second binding layer 14 disposed on a side of the first insulating layer 13 away from the first binding layer 12. The second binding layer 14 includes a plurality of second wirings 141. The second wirings 141 include a second surface S3. The first protrusion portions 171 are in contact with the second surface S3.

It is to be understood that according to the present embodiments, by forming the second binding layer 14 on the upper surface of the first insulating layer 13, the first protrusion portions 171 are in contact with both the first surface S2 and the second surface S3. That is, it is only needed to form the first notches 30 at the first insulating layer 13, which can simultaneously increase the contact area of the binding terminals 17 with the first binding layer 12 and the second binding layer 14, and improve the binding effect.

With continued reference to FIG. 3, it is to be noted that both the first binding layer 12 and the second binding layer 14 are disposed in the frame area A2 of the display panel 100, and serve only as wiring for transmitting the electrical signal of the binding terminals 17 to the display area A1. Each second wiring 141 is electrically connected to each corresponding first wiring 121 through a first via 130 in the first insulating layer 13, so that the first wiring 121 and an adjacent second wiring 141 transmit the same signals, and one of the binding terminals 17 is simultaneously bound to the first wiring 121 and the second wiring 141.

In one embodiment, the first binding layer 12 is prepared in the same process as a gate layer (not shown) of the display panel 100, and the second binding layer 14 is prepared in the same process as source and drain layer(s) (not shown) of the display panel 100. The gate layer is typically made of molybdenum, and the source and drain layer(s) is typically made of aluminum. The impedance of aluminum is lower than that of molybdenum, so that the electrical connection of the first wirings 121 to the second wirings 141 can serve to reduce the impedance.

In one embodiment, each first notch 30 is filled entirely with the corresponding first protrusion portion 171. It is to be understood that when the thickness of the film layers for forming the binding terminal 17 is large (greater than 5 microns), the first notch 30 is completely filled with the binding terminal 17.

Next, referring to FIG. 5, it is a cross-sectional view of a second structure of the display panel in FIG. 2 taken along the A-A′ direction. In the present embodiment, the first surface S2 is disposed close to the light-emitting side of the display panel 100. The structure of FIG. 5 differs from that of FIG. 3 in that, in the direction perpendicular to the side surface S1, the width w of the first notch 30 gradually increases in the light emitting direction of the display panel 100.

It is to be understood that in the embodiment, the first notch 30 is set to have an inclined bottom surface, so that the first protrusion portion 171 has different widths along the direction perpendicular to the side surface S1. Specifically, the width of the first protrusion portion 171 close to the second surface S3 is larger than that of the first protrusion portion 171 close to the first surface S2, so that the contact area between the first protrusion portion 171 and the second binding layer 14 can be further increased, and the contact impedance between the binding terminal 17 and the second binding layer 14 can be further reduced.

In one embodiment, the first notch 30 is partially filled with the corresponding first protrusion portion 171. That is, the first notch 30 contains, in addition to the first protrusion portion 171, an air layer or other film layers.

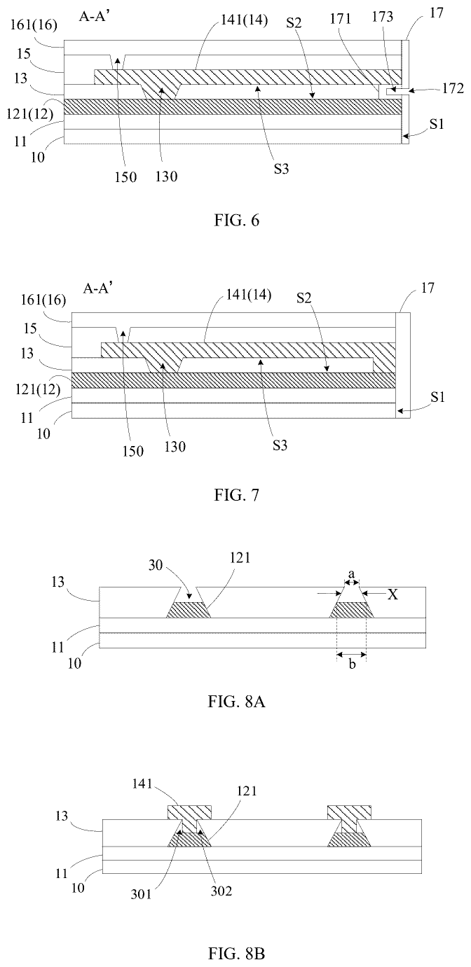

FIG. 6 is a cross-sectional view of a third structure of the display panel in FIG. 2 taken along the A-A′ direction. In the present embodiment, in the direction perpendicular to the side surface S1, a first opening 172 is formed in the binding terminal 17, and a first groove 173 is formed in the first protrusion portion 171. The first opening 172 communicates with the first groove 173. An air layer is formed in each of the first groove 173 and the first opening 172.

It is to be understood that when the binding terminal 17 is formed by the sputter coating, a part of the sputtered material (i.e., the first protrusion portion 171) falls into the first notch 30 and covers the inner wall of the first notch 30. When the thickness of the film layer formed by sputter coating is thin (greater than 0 and less than or equal to 5 microns), the first notch 30 cannot be filled entirely with the first protrusion portion 171. That is, the first notch 30 contains the air layer other than the first protrusion portion 171.

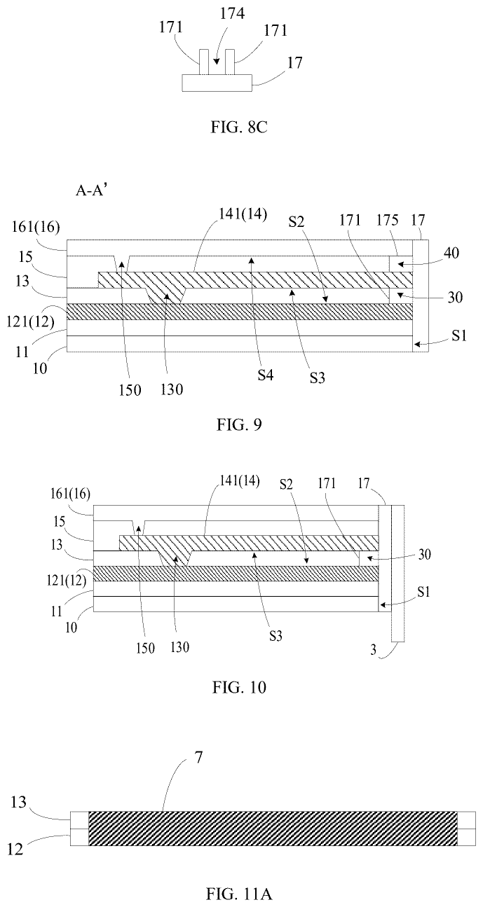

Next, FIG. 7 illustrates a cross-sectional view of a fourth structure of the display panel in FIG. 2 taken along the A-A′ direction, and FIGS. 8a to 8C are schematic diagrams of basic structures of components in a second manufacturing process of the display panel. Specifically, FIGS. 8a and 8b are schematic side views of the display panel 100, and FIG. 8c is a top view of the binding terminal 17. In the present embodiment, the first surface S2 is disposed close to the light-emitting side of the display panel 100. In the direction parallel to the first surface S2 and the side surface S1 (i.e., in the direction of the intersection line between the first surface S2 and the side surface S1), the width X of the first notch 30 decreases gradually along the light-emitting direction of the display panel 100. That is, in the present embodiment, the first notch 30 in the embodiment has a small upper end and a large lower end (a<b).

It is to be understood that when the first notch 30 is of a structure in which the upper end is small and the lower end is large, and other film layers are formed on the first insulating layer 13, the other film layers do not completely cover the entire first notch 30, but only an area corresponding to the upper end. Areas inside the first notch 30 other than the area corresponding to the upper end are shielded by the first insulating layer 13, thereby forming a void. A part of the sputtered material may be deposited in the void in the subsequent sputter coating process, thereby increasing the effective conductive area.

In one embodiment, the display panel includes the second binding layer 14 disposed on the side surface of the first insulating layer 13 away from the first binding layer 12. The second binding layer 14 includes the plurality of second wirings 141. In the light-emitting direction of the display panel 100, a first concave 174 is formed in the first protrusion portion 171 and filled with the second wiring(s) 141.

It is to be understood that in the present embodiment, a portion of each second wiring 141 disposed on the first insulating layer 13 is formed in the first notch 30 so as to contact the first surface S2 of the first wirings 121, but the second wiring 141 does not completely fill the first notch 30. Specifically, as shown in FIG. 8b, since the first notch 30 has the small upper end and the large lower end, a first gap 301 and a second gap 302 are formed between the prepared second wiring 141 and the first notch 30, and a portion of the sputtered material may be deposited in the first gap 301 and the second gap 302 when the binding terminal 17 is subsequently formed by sputter coating, thereby increasing the contact area of the binding terminal 17 with the first binding layer 12 and the second binding layer 14. FIG. 8c shows the cross-sectional shape of the binding terminal 17, in which the first concave 174 is formed in the first protrusion portion 171, so that the first protrusion portion 171 is divided into two parts, the left side part of the first protrusion portion 171 fills the first gap 301, and the right side part of the first protrusion portion 171 fills the second gap 302. In other words, the first protrusion portion 30 is filled with the first protrusion portion 171 and the second wiring 141.

It is to be noted that the material of the first protrusion portion 171 may be the same as or different from that of the second binding layer 14.

In one embodiment, in the direction parallel to the first surface S2 and the side surface S1, the width a of a side of the first notch 30 close to the second wirings 141 is greater than or equal to 0.1 microns and less than or equal to 1 microns, and the width b of a side of the first notch 30 close to the first wirings 121 is greater than or equal to 2 microns and less than or equal to 5 microns. The difference between the width b of the side of the first notch 30 close to the first wirings 121 and the width “a” of the side of the first notch 30 close to the second wirings 141 is greater than 2.

Next, FIG. 9 is a cross-sectional view of a fifth structure of the display panel in FIG. 2 in the A-A′ direction. In the present embodiment, the display panel includes a second insulating layer 15 and a third binding layer 16. The second insulating layer 15 is disposed on a side of the second insulating layer 14 away from the first insulating layer 13, where a second notch 40 is formed in an area of the second insulating layer 15 close to the side surface S1. The third binding layer 16 is disposed on a side of the second insulating layer 15 away from the second binding layer 14. The third binding layer 16 includes a plurality of third wirings 161 including a third surface S4. The binding terminal 17 includes a second protrusion portion 175 formed in the second notch 40, so that the second protrusion portion 175 is in contact with a surface of the second binding layer 14 away from the first insulating layer 13 and the third surface S4.

It is to be understood that the second protrusion portion 175 in the second notch 40 is in contact with the second wirings 141 and the third wirings 161, so that the contact area of the binding terminal 17 with the second binding layer 14 and the third binding layer 16 is increased. In the embodiment, by forming the first notch 30 at the first insulating layer 13 and the second notch 40 at the second insulating layer 15 (wherein a method of forming the second notch 40 refers to FIGS. 4a to 4d, or FIGS. 8a to 8c), the contact area of the binding terminal 17 with the first binding layer 12, the second binding layer 14, and the third binding layer 16 is increased, thereby improving the binding effect.

It is to be noted that the third binding layer 16 is disposed in the frame area A2 of the display panel 100, and each third wiring 161 is electrically connected to the second wiring 141 through a second via 150 on the second insulating layer 15. The adjacent first wiring 121, the second wiring 141 and the third wiring 161 transmit the same signal, and the binding terminal 17 is simultaneously bound to the first wiring 121, the second wiring 141 and the third wiring 161.

In one embodiment, the third binding layer 16 is prepared in the same process as the pixel electrode layer (not shown) of the display panel 100. The third wiring 161 is also electrically connected to the second wiring 141 to reduce the impedance.

Next, FIG. 10 is a schematic diagram of a basic structure of a display device according to the embodiments of the present disclosure. The display device includes a flexible circuit board 3 and the display panel 100. The flexible circuit board 3 is electrically connected to the binding terminal 17 of the display panel 100. The structure and preparation method of the display panel 100 are shown in FIGS. 2 to 9, and details are not repeated herein.

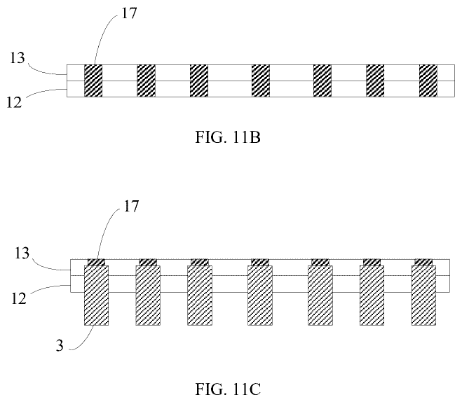

Next, FIGS. 11a to 11c are schematic diagrams of the basic structure of each component in the manufacturing process of the display device according to the embodiments of the present disclosure. It is to be noted that FIGS. 11a to 11c are schematic diagrams of a side view of the display panel 100, and only show the first binding layer 12, the first insulating layer 13, the binding terminals 17, and the flexible circuit boards 3. Specifically, as shown in FIG. 11a, an entire layer of a metal film 7 is first formed on the side surface of the display panel. Then, the metal film 7 is patterned to form the plurality of binding terminals 17, as shown in FIG. 11b. The flexible circuit boards 3 are correspondingly bound to the binding terminals 17, as shown in FIG. 11c, thereby completing the preparation of the display device. It is to be noted that the first notches 30 are formed in an area where the first insulating layer 13 is blocked by the binding terminals 17, and the first protrusion portions 171 are disposed on the binding terminals 17 and formed in the first notches 30. The first protrusion portions 171 are in contact with the first surface S2 of the first wirings 121, so that the effective conductive area of the binding area can be improved, the conductivity of the lines is improved, the number of conductive electrons is large, the contact impedance is low, the risk of abnormal binding is reduced, the product reliability is improved, and the product yield is improved.

It is to be noted that the display device according to the embodiments of the present disclosure may be a product or a component having a display function such as a mobile phone, a tablet computer, a notebook computer, a television set, a digital camera, or a navigator.

The display panel and the display device in the embodiments of the present disclosure are described in detail. It is to be understood that the exemplary embodiments described herein are to be considered as illustrative only, for purposes of aiding in the understanding of the methods of the disclosure and its core ideas, and not for purposes of limiting the disclosure.

What is claimed is:

1. A display panel comprising:
a substrate, wherein a binding terminal is disposed on at least a side surface of the substrate;
a first binding layer disposed on the substrate, the first binding layer comprising a plurality of first wirings, and the plurality of first wirings comprising a first surface; and
a first insulating layer in contact with the first surface, wherein a first notch is disposed in an area of the first insulating layer close to the side surface;
wherein a first protrusion portion is disposed on the binding terminal and formed in the first notch to be in contact with the first surface.

2. The display panel according to claim 1, wherein the first surface is disposed close to a light-emitting side of the display panel, and in a direction parallel to the first surface and the side surface, a width of the first notch gradually increases along a light-emitting direction of the display panel.

3. The display panel according to claim 2, wherein the display panel comprises a second binding layer disposed on a side of the first insulating layer away from the first binding layer; the second binding layer comprises a plurality of second wirings; and the plurality of second wirings comprise a second surface; and
the first protrusion portion is in contact with the second surface.

4. The display panel according to claim 3, wherein the first notch is filled entirely with the first protrusion portion.

5. The display panel according to claim 4, wherein in the light-emitting direction of the display panel, the width of the first notch gradually increases in a direction perpendicular to the side surface.

6. The display panel according to claim 3, wherein the first notch is partially filled with the first protrusion portion.

7. The display panel according to claim 6, wherein, in a direction perpendicular to the side surface, a first opening is formed in the binding terminal, a first groove is formed in the first protrusion portion, and the first opening communicates with the first groove; and
an air layer is formed in each of the first groove and the first opening.

8. The display panel according to claim 1, wherein the first surface is disposed close to a light-emitting side of the display panel, and in a direction parallel to the first surface and the side surface, a width of the first notch gradually decreases along a light-emitting direction of the display panel.

9. The display panel according to claim 8, wherein the display panel comprises a second binding layer disposed on a side of the first insulating layer away from the first binding layer, and the second binding layer comprises a plurality of second wirings; and
in the light-emitting side of the display panel, a first concave is formed in the first protrusion portion and filled with the second wirings.

10. The display panel according to claim 9, wherein, in a direction parallel to the first surface and the side surface, a width of a side of the first notch close to the second wirings is greater than or equal to 0.1 microns and less than or equal to 1 microns, a width of a side of the first notch close to the first wirings is greater than or equal to 2 microns and less than or equal to 5 microns, and a difference between the width of the side of the first notch close to the first wirings and the width of the side of the first notch close to the second wirings is greater than or equal to 2 microns.

11. The display panel according to claim 9, wherein the display panel comprises:
a second insulating layer disposed on a side of the second binding layer away from the first insulating layer, wherein a second notch is formed in an area of the second insulating layer close to the side surface; and
a third binding layer disposed on a side of the second insulating layer away from the second binding layer, wherein the third binding layer comprises a plurality of third wirings, and the plurality of third wirings comprise a third surface;
wherein a second protrusion portion is disposed on the binding terminal and in the second notch, the second protrusion portion is in contact with both the third surface and a side of the second binding layer away from the first insulating layer.

12. A display device comprising a flexible circuit board and a display panel, wherein the flexible circuit board is electrically connected to a binding terminal of the display panel and the display panel comprises:
a substrate, wherein a binding terminal is disposed on at least a side of the substrate;
a first binding layer disposed on the substrate, the first binding layer comprising a plurality of first wirings, and the plurality of first wirings comprising a first surface; and
a first insulating layer in contact with the first surface, wherein a first notch is disposed in an area of the first insulating layer close to the side surface;
wherein a first protrusion portion is disposed on the binding terminal and formed in the first notch to be in contact with the first surface.

13. The display device according to claim 12, wherein the first surface is disposed close to a light-emitting side of the display panel, and in a direction parallel to the first surface and the side surface, a width of the first notch gradually increases along a light-emitting direction of the display panel.

14. The display device according to claim 13, wherein the display panel comprises a second binding layer disposed on a side of the first insulating layer away from the first binding layer; the second binding layer comprises a plurality of second wirings, and the plurality of second wirings comprise a second surface; and
the first protrusion portion is in contact with the second surface.

15. The display device according to claim 14, wherein the first notch is filled entirely with the first protrusion portion.

16. The display device according to claim 14, wherein the first notch is partially filled with the first protrusion portion.

17. The display device according to claim 16, wherein, in a direction perpendicular to the side surface, a first opening is formed in the binding terminal, a first groove is formed in the first protrusion portion, and the first opening communicates with the first groove; and
an air layer is formed in each of the first groove and the first opening.

18. The display device according to claim 12, wherein the first surface is disposed close to a light-emitting side of the display panel, and in a direction parallel to the first surface and the side surface, a width of the first notch gradually decreases along a light-emitting direction of the display panel.

19. The display device according to claim 18, wherein the display panel comprises a second binding layer disposed on a side of the first insulating layer away from the first binding layer, and the second binding layer comprises a plurality of second wirings; and
in the light-emitting side of the display panel, a first concave is formed in the first protrusion portion and filled with the second wirings.

20. The display device according to claim 19, wherein the display panel comprises:
a second insulating layer disposed on a side of the second binding layer away from the first insulating layer, wherein a second notch is formed in an area of the second insulating layer close to the side surface; and
a third binding layer disposed on a side of the second insulating layer away from the second binding layer, wherein the third binding layer comprises a plurality of third wirings, and the plurality of third wirings comprise a third surface;
wherein a second protrusion portion is disposed on the binding terminal and in the second notch, the second protrusion portion is in contact with both the third surface and a side of the second binding layer away from the first insulating layer.
